(19) United States
(12) Patent Application Publication
(10) Pub. No.: US 2008/0088303 A1
(43) Pub. Date: Apr. 17, 2008

(54) Concept for detecting a contact with a game device

(76) Inventor: Walter Englert, Burgrieden (DE)

Correspondence Address: GLENN PATENT GROUP, 3475 EDISON WAY, SUITE L, MENLO PARK, CA, 94025, US

(21) Appl. No.: 11/672,879

(22) Filed: Feb. 8, 2007

(30) Foreign Application Priority Data
Oct. 12, 2006 (DE) 102006048385.5
Jan. 12, 2007 (DE) 102007001820.9

(51) Int. Cl. G01R 33/00

(52) U.S. Cl. 324/226

(57) ABSTRACT

A method of detecting a contact between a player and a ball in a ball game, comprising a step of generating a magnetic field which may be associated with the player, the magnetic field being generated with a code sequence or a frequency which differ from a code sequence or a frequency which may be associated with the other player of the ball game, a step of detecting the magnetic field which may be associated with the player, and a step of determining the code sequence or the frequency with which the magnetic field was sent so as to obtain, on the basis of the code sequence or frequency, ball-contact information indicating whether the player had contact with the ball.

The present invention relates to a concept for detecting a contact with a game device as may be employed, for example, in a ball game for detecting a contact between a player and a ball.

For quite some time, various interest groups have wished to study and understand the sequence of movements of moving objects and/or persons, which requires, for example, an exact indication of the object's position in space and time or the determination of contacts of the object being moved. What is of particular interest here are, among other things, game balls, in particular in commercialized types of sport, such as footballs, or soccer balls, which are highly accelerated in three-dimensional space, as well as tennis or golf balls. A question of who was the last to touch the object of the game, how it was hit and in which direction it was accelerated further may be decisive for the outcome of the game, depending on the type of game.

Game devices that are used in high-performance sports, such as tennis balls, golf balls, footballs and the like, nowadays can be accelerated to extremely high speeds, so that the detection of the object, or game device, during the movement requires highly sophisticated technology. Technical means employed so far—such as cameras—either completely fail to meet the requirements set forth above, or meet them only to an insufficient degree. Also, the methods hitherto known for ball contact determination still leave a large margin with regard to precision.

In various types of sports, including football, or soccer, for example, there is often an interest in establishing certain statistics regarding the course of a match. Such statistics include, e.g., the distribution of ball possession between the two opposing teams. It is also interesting to know how many times the ball is lost to a player of the opposing team in tackles, or how many bad passes occur in a match.

Generally, such statistics are established by visually observing the course of match. To this end, there are generally persons in a stadium who evaluate, for example, the ball contacts of the respective players so as to obtain the above-mentioned statistical values. This approach is generally very demanding in terms of effort, costly and also prone to mistakes due to human error.

It is thus the object of the present invention to provide an improved concept for determining a player's contact with a ball.

This object is achieved by a device comprising the features of claim 1, by a ball used in a game as claimed in claim 8, by a system as claimed in claim 17, by a method as claimed in claim 18, and by a computer program as claimed in claim 19.

The present invention is based on the findings that the contact a player has with a device used in a game, or a ball, may be determined in that, for example in a football, or soccer, match, a device is mounted to the shoe of a football player in order to send out a magnetic signal characterizing the player, which can then be detected by a magnetic-field sensor within a ball used in the game and which may thereupon be associated with the player.

In accordance with embodiments, the device comprises a magnetic-field generator, in particular a coil, a source of energy or a battery for supplying the coil, and a coil driver or microcontroller to be able to generate magnetic signals characteristic of the player.

In accordance with one embodiment of the present invention, the magnetic-field generator is configured to send the magnetic field with a code sequence or a frequency which differ from the code sequence or a frequency exhibited by a different device mountable to a different player of the ball game.

In accordance with embodiments, the device which is mountable to the player may be housed within a thin elastic housing the size of a check card, i.e. it may be a chip card which may be placed, for example, on a football shoe or a shin guard of the player. Magnetic signals sent out by the device have a very short range and are measured by the magnetic-field sensor located within the ball so that they may subsequently be associated with the player located in the vicinity of the ball. The chip card on a player's shoe only sends out magnetic signals, but it may not accept or evaluate any signals.

In accordance with a further aspect, the present invention provides a device or a ball used in a game having a magnetic-field sensor for detecting the magnetic field which may be associated with the player of the ball game, and having a means for determining a code sequence or a frequency with which the magnetic field was sent to obtain an indication, on the basis of the code sequence or the frequency, as to which player had contact with the ball.

In accordance with embodiments of the present invention, the magnetic-field sensor is a three-dimensional magnetic-field sensor. The magnetic-field sensor located within the ball includes a Hall sensor or a magneto-resistive element. In this context, no energy is gained from the magnetic field created by the device mountable on the player so as to supply the ball with energy. For energy supply purposes, the ball is provided with a battery, in accordance with embodiments. The ball does not represent a transponder since it does not communicate with the chip card of the player across the distance of the magnetic field. A communication with a central evaluating device is performed exclusively, for example, across a 2.4 GHz radio path and, additionally, in a manner offset in time, for example not before the end of the game. To this end, the ball used in the game comprises a memory to store ball-contact information, for example, over the entire course of the game. At the end of a game, the ball-contact information on the memory may possibly be read out with a time indication via an interface which may be a radio interface or a wire-connected interface. With this information, an evaluation may be performed as to who kicked the ball how many times, for example, and within which period of time how many ball contacts were made. In addition, it may be established, for example, whether the ball arrived at a player of one's own team or a player of the opponents. In addition, the inventive concept may be used to determine whether a move was successful, for example.

In accordance with embodiments, the information received from the magnetic-field sensor within the ball, i.e. a code sequence or a frequency with which the magnetic field was transmitted, may be transmitted to a central evaluating device via a radio transmitter integrated within the ball. In order to obtain ball-contact information close to real time, transmission of the information from the ball to the evaluating device may be performed immediately, in accordance with embodiments.

An advantage of the present invention lies in the fact that contacts between balls used in the game and players may be detected individually and reliably, and that statistical evaluation of a course of a game may thus be simplified.

Preferred embodiments of the present invention will be explained below in more detail with reference to the accompanying figures, wherein:

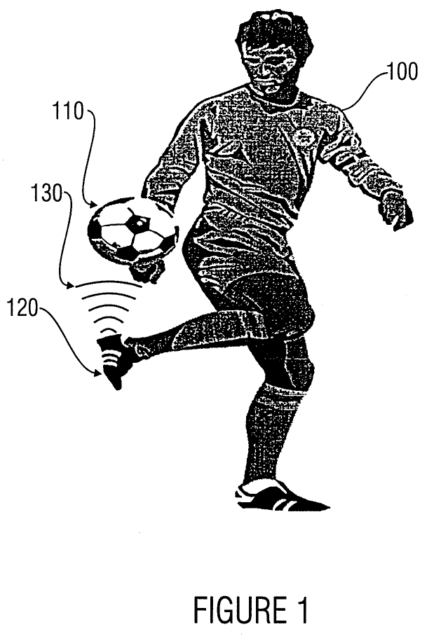

FIG. 1 shows a player with a football, or soccer ball, as an example of an application of the inventive concept;

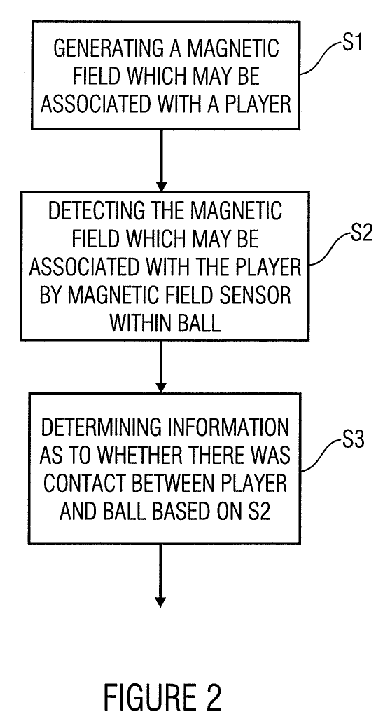

FIG. 2 is a flowchart for illustrating a method of detecting a contact between a player and a ball in accordance with an embodiment of the present invention;

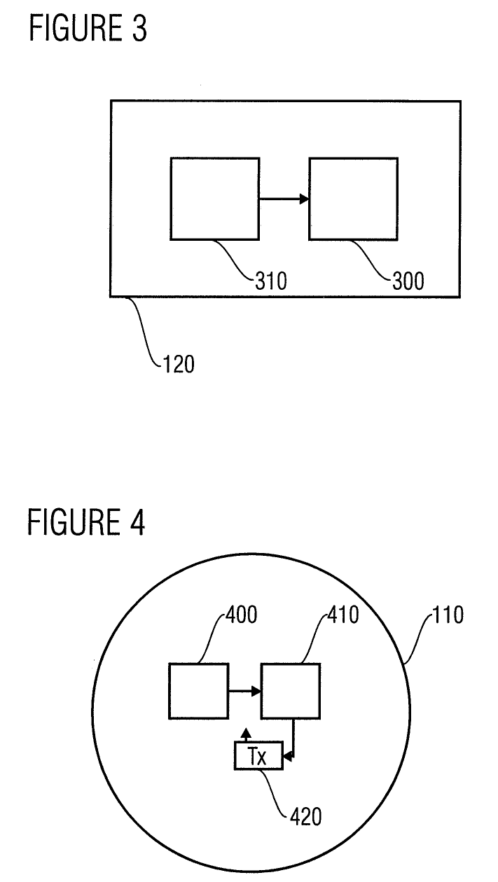

FIG. 3 shows a device which is mountable to a player of an example, in accordance with an embodiment of the present invention;

FIG. 4 shows a ball in accordance with an embodiment of the present invention; and

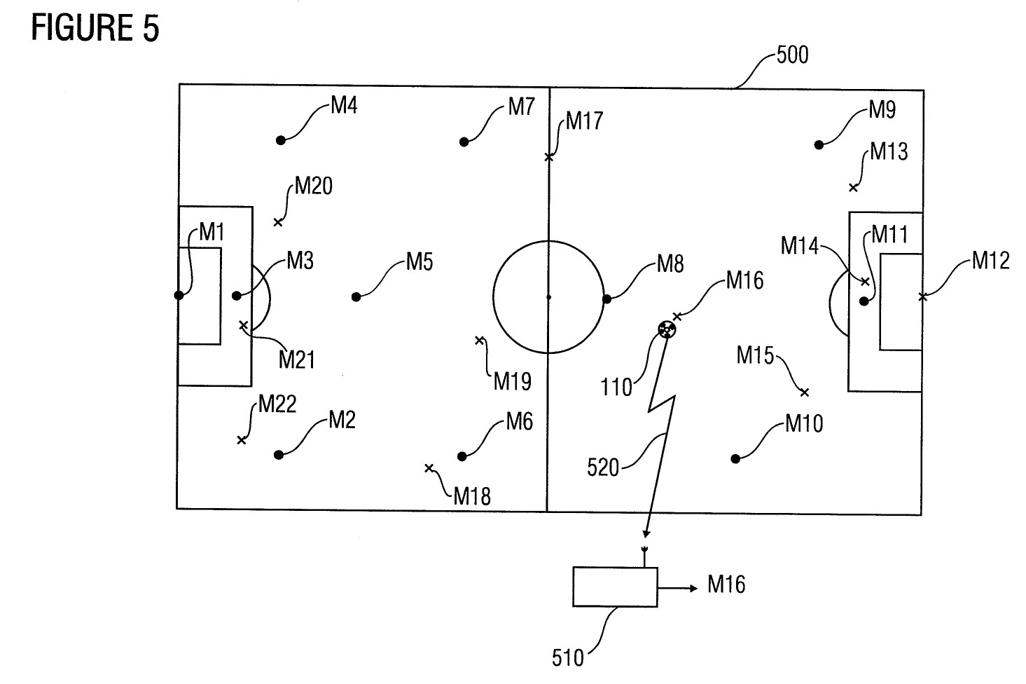

FIG. 5 is a schematic sketch of a football pitch comprising 22 players and a ball as an example of use of the present invention.

It is to be noted, with regard to the following description, that in the various embodiments, functional elements which are identical or have identical actions exhibit identical reference numerals, and that, thus, the descriptions of the functional elements within the various embodiments represented below are interchangeable.

In order to improve one's skill at a ball game or to be able to compare oneself with other players, objective data must be obtained in a simple manner. This data would have to be visualized such that a training feedback or a comparison with other players is possible. For this purpose, appropriate components placed within the device used in the game and on the player and, if need be, a central evaluating device are provided.

In a low-cost system, a detection of a contact between a device used in a game and a player cannot be effected by the run times of radio signals. To this end, incoming radio signals would have to be compared, for example, with a highly accurate time reference. Also, a network would have to be constructed, within which all times measured are compared so as to determine the player located closest to the ball.

Therefore, conclusions are drawn, on the basis of a magnetic signal being sent out, as to who had contact with the ball. This principle is schematically represented in FIG. 1.

FIG. 1 shows a player 100 and a ball 110. One shoe of the player 100 has a device 120 attached to it to be able to ascertain a contact between the player 100 and the ball 110. To this end, the device 120 sends out a magnetic signal 130 which characterizes the player 100 and/or may be associated with the player. A magnetic-field sensor within the ball 110 may detect the magnetic signal 130 and, based thereon, provide an indication as to whether there has been a contact between the player 100 and the ball 110. In this context, a method of detecting a ball contact in accordance with an embodiment of the present invention is depicted in FIG. 2.

In a first step S1, the device 120 generates a magnetic field 130 which may be associated with the player 100, the magnetic field 130 being generated with a code sequence or a frequency different from a code sequence or a frequency exhibited by a different device which is mountable to a different player of the ball game.

In a second step S2, the ball 110 detects the magnetic field 130, which may be associated with the player 100, using a magnetic-field sensor mounted within the ball, and determines, in a third step S3, the code sequence or the frequency with which the magnetic field 130 was sent from the device 120 so as to provide an indication, on the basis of the code sequence or frequency, as to which player had contact with the ball 110.

FIG. 3 shows a device 120 which is mountable to a player 100 in a ball game so as to be able to ascertain a contact of the player 100 with a ball 110, in accordance with an embodiment of the present invention.

The device 120 comprises a magnetic-field generator 300 coupled to an energy source 310 so as to be supplied with energy by the energy source 310.

The magnetic-field generator 300 serves to generate a magnetic field 130 which may be associated with the player 100, the magnetic-field generator 300 being configured to send the magnetic field with a code sequence or a frequency which differ from the code sequence or a frequency exhibited by a different device 120 mountable to a different player of the ball game.

In accordance with embodiments of the present invention, the magnetic-field generator 300 comprises a coil and a coil driver within a coil wiring, the coil wiring being configured to drive a current through the coil and to detect no voltage induced in the coil.

For example, the coil driver may comprise a microcontroller providing a code sequence which may be a bit sequence, for example. In accordance with this bit sequence, current is driven through the coil of the magnetic-field generator 300, i.e., for example, current is flowing at a logical “1”, and no current is flowing at a logical “0”. Similar to a CDMA method (CDMA=code division multiple access), a characteristic code and/or bit sequence may thus be generated for each player of the ball game and be converted to magnetic pulses via the coil.

In accordance with a further embodiment, the coil driver may control the coil of the magnetic-field generator 300 with a predefined frequency. Thus, a coil enable signal, which may be a current or a voltage, is applied to the coil with a frequency which may be associated with the player 100. In this embodiment, the players may thus be differentiated by means of frequencies of the alternating magnetic field generated, similarly to an FDMA method (FDMA=frequency division multiple access).

To be able to reliably associate a ball contact with an individual player, the magnetic-field generator 300 is configured, in accordance with embodiments, to generate the magnetic field with a predetermined detection range, the detection range preferably being smaller than or equal to 50 cm, and particularly preferably smaller than or equal to 20 cm.

In accordance with an embodiment of the present invention, the energy source 310 is a battery. In this context, the device 120 is supplied via a lithium battery, for example. The capacity of the battery is designed such that the functionality of the electronic system within the device 120 is ensured for, for example, 1000 hours. With an average playing time of one hour per day, the battery would thus last for about 3 years.

In accordance with an embodiment, the device 120 comprises geometric dimensions such that the device 120 may be mounted, for example, to a football shoe or a shin guard of the player 100. To this end, the device 120 may be configured, for example, in the format of a check card. Thus, the device 120, in the form of a flexible check card, may be mounted, for example, in the tongue of a football shoe or on a shin guard. Naturally, it is also feasible for the device 120 to be permanently integrated into a football shoe.

In other types of sports, the device 120 may be mounted, e.g., within a racquet, a bat, a club, a stick, a batter, a glove or a watchstrap so as to be able to ascertain ball contacts. Geometric dimensions of the device 120 are adjusted to the respective field of application and/or to the type of sport contemplated.

FIG. 4 depicts a ball 110 in accordance with an embodiment of the present invention.

The ball 110 comprises a magnetic-field sensor 400 coupled to a means 410 for determining a code sequence or a frequency with which the magnetic field 130 was sent. In the embodiment shown in FIG. 4, the means 410 is additionally coupled to a radio transmitter 420.

The magnetic-field sensor 400 serves to detect a magnetic field 130, or an alternating magnetic field, which may be associated with a player 100 of the ball game. In accordance with embodiments, the magnetic-field sensor 400 comprises a Hall sensor or a magneto-resistive element. In accordance with a preferred embodiment of the present invention, the magnetic-field sensor 400 is a three-dimensional magnetic-field sensor, i.e. three components of a magnetic field which are perpendicular to one another, respectively, and correspond to the space coordinates, as well as their magnitudes may be measured with this magnetic-field sensor.

The magnetic-field sensor 400 passes its measured values to the means 410 which will determine, on the basis of the measured values, a code sequence or a frequency with which the magnetic field was sent. In accordance with an embodiment of the present invention, for determining the code sequence, the means 410 comprises a correlator to compare the magnetic pulses received from the magnetic-field sensor 400, and/or the logic sequence which may be associated with the magnetic pulses, with the reference sequences stored within the ball 110. Different bit sequences preferably comprise auto- and cross-correlation properties, so that the bit sequences may be detected in a manner which is as free from errors as possible. The various bit sequences which may be associated with the players are thus orthogonal to one another, in accordance with preferred embodiments.

In accordance with a further embodiment, means 410 may also pass on the code sequence and/or bit sequence received and/or detected to the radio transmitter 420 so as to send the code sequence to a central evaluating device, not shown in FIG. 4. On the basis of a correlation result of the evaluating device, ball-contact information, or an indication as to which player had contact with the ball 110, may be received. The ball-contact information may additionally also be provided with time information by the central evaluating unit. This embodiment has the advantage that a ball electronic system may be kept simple and therefore at low cost. Computing algorithms and, thus, high-power evaluating algorithms take place in the central evaluating device, which may be a PC (personal computer), for example.

If the ball-contact information is not required in real time, but, e.g., not until the end of the match, the ball 110 may further comprise, in accordance with embodiments, a means for providing time information so as to associate the time information with ball-contact information. Thereby it is possible to make a statement about which player had contact with the ball 110 at what time.

In embodiments, the ball 110 further comprises a memory to store the indication and/or the ball-contact information signal along with the respective time information, as the situation may be. Using an interface, which may be a wire-connected, but also a radio interface over the transmitter 420, the memory content of the memory may be read out, for example, after the end of a match. Using the ball-contact information and the associated time information, one may then determine how many ball contacts a player 100 had. It is even possible to make statistic statements about how successful passes were, since the target of a pass may be determined by a time comparison. This may be used to detect the following, for example:
Who lost the ball how many times to the opponent?
Were the ball contacts constant over the playing time and was there a drop in performance?
Who played how many passes to whom?
How often did a move pass several players of the same team?

The magnetic-field sensor 400, particularly a three-dimensional magnetic-field sensor, is capable of verifying not only the presence of the magnetic field 130, but also its intensity. By means of the intensity, i.e. the magnitude of the magnetic-field strength measured, a statement may be made, in accordance with further developments of the present invention, as to the likelihood that a player had a ball contact. This may be of interest, for example, when several players are fighting for the ball 110, and when it cannot be decided with the naked eye as to which player was the last to touch the ball 110. Such statements are relevant, for example, for corner or offside decisions.

A current supply of the ball's electronic system may be realized, in a known manner, in two different ways. On the one hand, it is possible to use an accumulator, which will require charging equipment, however. On the other hand, a primary battery may be used within the ball, it being impossible, however, to replace said primary battery within the ball.

In the case of the accumulator version, a charging coil is mounted within the ball 110, by means of which the accumulator may be inductively charged. With the battery version, the ball is supplied via lithium batteries. The capacity is designed, for example, such that the electronic system within the ball is ensured to function for 1000 hours. With an average playing time of one hour per day the battery would last approximately three years.

An example of use of the inventive concept is detecting ball contacts in a football, or soccer, match. In this context, FIG. 5 schematically shows a system for detecting a contact between players and a ball 110 in accordance with an embodiment of the present invention.

FIG. 5 shows a football pitch 500, 22 players who are represented schematically, players of a first team being schematically represented by filled circles, and players of a second team being schematically represented by crosses, as well as a ball 110 and a central evaluating device 510.

Each of the 22 players on the pitch has a device 120 comprising a magnetic-field generator 300 attached to them. Each of the 22 inventive devices generates a magnetic field which may be uniquely associated with each player, as is indicated in FIG. 5 by reference numerals M1 to M22. As has been previously described, the association of magnetic field [symbol] player may be effected via a code and/or bit sequence or a frequency of the magnetic field.

As has already been described above, the ball 110 is equipped with a preferably three-dimensional magnetic-field sensor which may comprise Hall sensors or magneto-resistive elements. In the embodiment depicted in FIG. 5, the ball 110 further comprises a radio transmitter so as to communicate with the central evaluating device 510 via the radio path 520.

In the scenario shown in FIG. 5, there is a ball contact between the player having the magnetic field M16 characteristic of him/her, and the ball 110. In close proximity to the device 120, which generates magnetic field M16 and is attached to the player, the ball measures the magnetic field generated, and associates the magnetic field measured with the player 100 on the basis of a detected bit sequence and/or a detected frequency. With a code sequence, the association is performed, in accordance with the embodiment, by means of a correlator. If a frequency differentiation is to be conducted, this may be effected, for example, using a tunable receive filter and/or band-pass filter. On the basis of the code sequence and/or the frequency, the ball 110 sends an indicator signal and/or an information signal to the central evaluating location 510 via the radio interface 520, the signal indicating which player had contact with the ball 110. In the scenario depicted in FIG. 5, the player in question is the player 100 having the characteristic magnetic field M16.

In accordance with embodiments, the ball 110 may also send only the bit sequence or the frequency to the central evaluating location 510, which will then perform the association of bit sequence [symbol] player and/or frequency [symbol] player.

Transmission of information from the ball 110 to the central evaluating location 510 is performed, in accordance with embodiments, via a 2.4 GHz radio path.

As has already been mentioned above, the radio transmission 520 may also be dispensed with, in accordance with embodiments, if the ball-contact information is not needed until after the end of the match, for example. However, in this case the ball 110 will preferably comprise a memory for storing the ball-contact information, preferably along with time information.

In the scenario comprising the radio path 520, depicted in FIG. 5, the central evaluating means 510 is configured to provide that ball-contact information which is received from the ball 110 via the radio path 520, with a time indication.

In accordance with embodiments, the central evaluating device 510 may also be a referee's watch, for example, so as to be able to provide ball-contact information to the referee on a display of the watch.

Thus, the present invention provides a low-effort and low-cost concept to be able to identify contacts between players and game devices. A further advantage of the present invention lies in the fact that it is also possible to make decisions with regard to goals by means of coils which are suitably mounted near the goal and which generate magnetic fields within a goal area, and by means of the magnetic-field sensor within the ball 110. Thus, the electronic system within the ball 110 may be designed such that the ball 110 may provide both ball-contact information and goal-decision information on the basis of magnetic-field measurements.

In addition, it is to be noted that the present invention is not limited to the respective components of the device 120, of the ball 110, or to the approach illustrated, since these components and methods may vary. The terms used are only intended to describe particular embodiments, and are not used in a limiting sense. If the singular form or indefinite articles are used in the description and in the claims, they shall also relate to the plural form of these elements, unless the overall context clearly indicates otherwise. The same applies in the opposite direction.

It shall be pointed out, in particular, that the inventive scheme may also be implemented in software, depending on the circumstances. The implementation may be performed on a digital storage medium, in particular a disk or a CD with electronically readable control signals which may cooperate with a programmable computer system and/or microcontroller in such a manner that the respective method is performed. Generally, the invention thus also consists in a computer program product having a program code, stored on a machine-readable carrier, for performing the inventive method of detecting a ball contact, when the computer program product runs on a computer and/or microcontroller. In other words, the invention may thus be realized as a computer program having a program code for performing the method, when the computer program runs on a computer and/or microcontroller.

1. A device (120) which is mountable to a player (100) of a ball game to be able to identify a contact of the player (100) with a ball (110), the device comprising:
a magnetic-field generator (300) for generating a magnetic field (130) which may be associated with the player, the magnetic-field generator (300) being configured to send the magnetic field (130) with a code sequence or a frequency which differ from a code sequence or a frequency exhibited by a different device which may be mounted to a different player of the example; and
a source of energy (310) for supplying the magnetic-field generator (300).

2. The device as claimed in claim 1, wherein the magnetic-field generator (300) comprises a coil and a coil driver within a coil wiring, the coil wiring being configured to drive a current through the coil and to detect no voltage induced within the coil.

3. The device as claimed in claim 2, wherein the coil driver is configured to control the coil with a code sequence or frequency which may be associated with the player (100).

4. The device as claimed in claims 2 or 3, wherein the coil driver comprises a microcontroller.

5. The device as claimed in any of claims 1 to 4, wherein the magnetic-field generator (300) is configured to generate the magnetic field (130) with a predetermined detection range, the detection range being smaller than or equal to 50 cm, and preferably smaller than or equal to 20 cm.

6. The device as claimed in any of the previous claims, wherein the source of energy (310) is a battery.

7. The device as claimed in any of the previous claims, wherein the device (120) may be mounted to a football shoe or a shin guard on a football player.

8. A ball (110) for a ball game, comprising:
a magnetic-field sensor (400) for detecting a magnetic field (130) which may be associated with a player (100) of the ball game; and
a means (410) for determining a code sequence or a frequency with which the magnetic field (130) was sent so as to obtain, on the basis of the code sequence or frequency, ball-contact information which indicates whether the player (100) had contact with the ball (110).

9. The ball as claimed in claim 8, wherein the magnetic-field sensor (400) comprises a Hall sensor.

10. The ball as claimed in claim 8, wherein the magnetic-field sensor (400) comprises a magneto-resistive element.

11. The ball as claimed in any of claims 8 to 10, wherein the magnetic-field sensor (400) is a three-dimensional magnetic-field sensor.

12. The ball as claimed in any of claims 8 to 11, the ball (110) further comprising a radio transmitter (420) for transmitting the ball-contact information.

13. The ball as claimed in any of claims 8 to 12, the ball (110) further comprising a means for providing time information to be able to associate the time information with ball-contact information.

14. The ball as claimed in any of claims 8 to 13, further comprising a memory to store the ball-contact information.

15. The ball as claimed in claim 14, comprising an interface to be able to read out a memory content of the memory.

16. The ball as claimed in any of claims 8 to 15, comprising a source of energy for supplying an electronic system of the ball.

17. A system for detecting a contact between a player (100) and a ball (110) in a ball game, comprising:
a device (120) which may be mounted to the player (100) to be able to ascertain the contact of the player (100) with the ball (110), comprising a magnetic-field generator (300) for generating a magnetic field (130) which may be associated with the player (100), the magnetic-field generator (300) being configured to send the magnetic field (130) with a code sequence or a frequency which differ from a code sequence or a frequency exhibited by a different device which may be mounted to a different player of the example, and an energy source (310) for supplying the magnetic-field generator (300); and
a ball (110) comprising a magnetic-field sensor (400) for detecting the magnetic field (130) which may be associated with the player (100) of the ball game, and
a means (410) for determining the code sequence or the frequency with which the magnetic field (130) was sent so as to obtain, on the basis of the code sequence or frequency, ball-contact information indicating whether the player (100) had a contact with the ball (110).

18. A method of detecting a contact between a player (100) and a ball (110) in a ball game, comprising:
generating a magnetic field (130) which may be associated with the player (100), the magnetic field being generated with a code sequence or a frequency which differ from a code sequence or a frequency which may be associated with the other player of the ball game;
detecting the magnetic field which may be associated with the player (100); and
determining the code sequence or the frequency with which the magnetic field (130) was sent so as to obtain, on the basis of the code sequence or frequency, ball-contact information indicating whether the player (100) had contact with the ball (110).

19. A computer program comprising a program code for performing the method as claimed in claim 18, when the program runs on a computer.
